(19) United States
(12) Patent Application Publication
(10) Pub. No.: US 2021/0028724 A1
(43) Pub. Date: Jan. 28, 2021

(54) TRANSDUCER DEVICE

(71) Applicant: TOYODA GOSEI CO., LTD., Kiyosu-shi, Aichi-ken (JP)

(72) Inventors: Yoshinao TAJIMA, Kiyosu-shi, Aichi-ken (JP); Shinji OGUCHI, Kiyosu-shi, Aichi-ken (JP); Tomoyuki TAINAKA, Kiyosu-shi, Aichi-ken (JP)

(21) Appl. No.: 16/982,639

(22) PCT Filed: Mar. 22, 2019
(86) PCT No.: PCT/JP2019/012209

§ 371 Date: Sep. 21, 2020

(30) Foreign Application Priority Data
Mar. 27, 2018 (JP) 2018-060397

(51) Int. Cl. H02N 1/00; G01L 1/14; G01L 1/26

(52) U.S. Cl. CPC H02N 1/006; G01L 1/26; G01L 1/14

(57) ABSTRACT

A transducer device includes a first dielectric layer, a first electrode layer and a second electrode layer that hold the first dielectric layer in a thickness direction, a second dielectric layer provided continuously from the first dielectric layer, a third electrode layer and a fourth electrode layer that hold the second dielectric layer in the thickness direction, and a controller. The controller calculates a command value of voltage to be applied to the first electrode layer and the second electrode layer and applies a voltage corresponding to the command value to the first electrode layer and the second electrode layer so that the first dielectric layer is deformed in the thickness direction. The controller measures a capacitance Cs of the second dielectric layer via the third electrode layer and the fourth electrode layer and calculates the command value in reference to the measured capacitance Cs.

### CROSS REFERENCE TO RELATED APPLICATIONS

This application is a U.S. national stage application of International Patent Application No. PCT/JP2019/012209 filed on Mar. 22, 2019, which claims priority to Japanese Patent Application No. 2018-060397 filed on Mar. 27, 2018, the contents of which are incorporated herein by reference.

### BACKGROUND

The present disclosure relates to a transducer device.

A typical transducer device includes a dielectric layer with a first electrode layer and a second electrode layer that hold the dielectric layer in the thickness direction of the dielectric layer. Such a transducer device functions as an actuator that deforms the dielectric layer in the thickness direction. Such a transducer device also functions as a sensor that detects a physical quantity (pressure or deformation amount) acting on the dielectric layer. The transducer device includes a controller connected to the first electrode layer and the second electrode layer.

When the transducer device functions as an actuator, the controller calculates a command value of voltage to be applied to the first electrode layer and the second electrode layer and applies a voltage corresponding to the command value to the first electrode layer and the second electrode layer so that the dielectric layer is deformed in the thickness direction. Further, when the transducer device functions as a sensor, the controller calculates a physical quantity acting on the dielectric layer in reference to an electrical signal from the first electrode layer and the second electrode layer.

When the transducer device functions as an actuator, the deformation amount of the dielectric layer in the thickness direction that results from the application of a voltage to the first electrode layer and the second electrode layer changes depending on surrounding environment such as temperature and humidity around the dielectric layer. Further, when the transducer device functions as a sensor, the physical quantity acting on the dielectric layer calculated in reference to an electrical signal from the first electrode layer and the second electrode layer changes depending on surrounding environment such as temperature and humidity around the dielectric layer.

To solve this problem, as described in Patent Document 1 and Patent Document 2, it may be possible to store changes in the deformation characteristics of the dielectric layer resulting from the changes in the surrounding environment and refer to the stored data in reference to the surrounding environment such as temperature and humidity so that the command value of the applied voltage is corrected and the calculated physical quantity acting on the dielectric layer is corrected.

When the transducer device functions as the actuator, correcting the command value of the applied voltage in reference to the surrounding environment such as temperature and humidity as described above prevents the deformation amount of the dielectric layer in the thickness direction from deviating to an unintended value due to the surrounding environment.

When the transducer device functions as the sensor, correcting the physical quantity acting on the dielectric layer calculated in reference to the surrounding environment such as temperature and humidity as described above prevents the physical quantity detected by the sensor from deviating from an appropriate value due to the surrounding environment.

### PRIOR ART DOCUMENTS

### Patent Documents

Patent Document 1: Japanese Patent No. 5131939
Patent Document 2: Japanese Laid-Open Patent Publication No. 2007-101338

### SUMMARY

However, when the command value of the applied voltage and the calculated physical quantity that acts on the dielectric layer are corrected in reference to the surrounding environment of the dielectric layer such as temperature and humidity, the changes in the deformation characteristics of the dielectric layer resulting from the changes in the surrounding environment need to be stored as data. This requires a significant amount of time and effort.

It is an object of the present disclosure to provide a transducer device capable of, without consuming time or effort, preventing the deformation amount of a dielectric layer when the transducer device functions as an actuator from deviating from an intended value due to the surrounding environment of the dielectric layer, and preventing a physical quantity detected when the transducer device functions as a sensor from deviating from an appropriate value due to the surrounding environment of the dielectric layer.

Means and operational advantages for solving the above-described problem will now be described.

A first aspect of a transducer device that solves the above-described problem includes a first dielectric layer, a first electrode layer and a second electrode layer that hold the first dielectric layer in a thickness direction, a second dielectric layer provided continuously from the first dielectric layer, a third electrode layer and a fourth electrode layer that hold the second dielectric layer in the thickness direction, and a controller that calculates a command value of voltage to be applied to the first electrode layer and the second electrode layer and applies a voltage corresponding to the command value to the first electrode layer and the second electrode layer so that the first dielectric layer is deformed in the thickness direction. The controller measures a capacitance Cs of the second dielectric layer via the third electrode layer and the fourth electrode layer and calculates the command value in reference to the measured capacitance Cs.

When the first dielectric layer is deformed in the thickness direction by applying a voltage to the first electrode layer and the second electrode layer, the deformation amount may change depending on the surrounding environment of the first dielectric layer such as temperature and humidity. This is because the relative permittivity of the first dielectric layer is changed by the surrounding environment of the first dielectric layer and such changes in the relative permittivity corresponding to the surrounding environment of the first dielectric layer is not taken into account to apply a voltage to the first electrode layer and the second electrode layer. In the above-described configuration, since the second dielectric layer is continuous from the first dielectric layer, the relative permittivity εr of the second dielectric layer is almost equal to the relative permittivity εr of the first dielectric layer. The relative permittivity εr of the second dielectric layer relates to the capacitance Cs of the second dielectric layer. The above-described command value is calculated in reference to the capacitance Cs of the second dielectric layer. When the voltage corresponding to the above-described command value calculated in such a manner is applied to the first electrode layer and the second electrode layer, the application of voltage to the first electrode layer and the second electrode layer is executed taking into account the changes in the relative permittivity corresponding to the surrounding environment of the first dielectric layer. As a result, the deformation amount when the first dielectric layer deforms as a result of the application of the voltage to the first electrode layer and the second electrode layer is prevented from deviating from an intended value due to the surrounding environment of the first dielectric layer. Accordingly, like in a case where the above-described command value is corrected in correspondence with the surrounding environment of the first dielectric layer, the changes in the deformation characteristics of the dielectric layer resulting from the changes in the surrounding environment of the dielectric layer do not need to be stored as data so that the command value is corrected with reference to the data. Thus, the time and effort to store the data are not required.

In the above-described transducer device, it is preferred that the controller obtain a relative permittivity εr of the second dielectric layer in reference to the measured capacitance Cs and use the relative permittivity εr as a relative permittivity εr of the first dielectric layer to calculate the command value. Instead of directly calculating the relative permittivity εr of the second dielectric layer in reference to the measured capacitance Cs as described above, the value on which the relative permittivity εr is reflected may be obtained so that the command value is calculated in reference to the obtained value.

A second aspect of a transducer device that solves the above-described problem includes a first dielectric layer, a first electrode layer and a second electrode layer that hold the first dielectric layer in a thickness direction, a second dielectric layer provided continuously from the first dielectric layer, a third electrode layer and a fourth electrode layer that hold the second dielectric layer in the thickness direction, and a controller that calculates a physical quantity acting on the first dielectric layer in reference to an electrical signal from the first electrode layer and the second electrode layer. The controller measures a capacitance Cs of the second dielectric layer via the third electrode layer and the fourth electrode layer and calculates the physical quantity in reference to the measured capacitance Cs.

The physical quantity acting on the first dielectric layer, calculated in reference to an electrical signal from the first electrode layer and the second electrode layer, may change depending on the surrounding environment of the first dielectric layer such as temperature and humidity. This is because the relative permittivity of the first dielectric layer is changed by the surrounding environment of the first dielectric layer and such changes in the relative permittivity corresponding to the surrounding environment of the first dielectric layer is not taken into account to calculate the physical quantity. In the above-described configuration, since the second dielectric layer is continuous from the first dielectric layer, the relative permittivity εr of the second dielectric layer is almost equal to the relative permittivity εr of the first dielectric layer. The relative permittivity εr of the second dielectric layer relates to the capacitance Cs of the second dielectric layer. The above-described physical quantity is calculated in reference to the capacitance Cs of the second dielectric layer. When the above-described physical quantity is calculated in this manner, the physical quantity is calculated taking into account the changes in the relative permittivity corresponding to the surrounding environment of the first dielectric layer. As a result, the physical quantity acting on the first dielectric layer, detected by the transducer device, is prevented from deviating from a proper value due to the surrounding environment of the first dielectric layer.

In the above-described transducer device, it is preferred that the controller obtain a relative permittivity εr of the second dielectric layer in reference to the measured capacitance Cs and use the relative permittivity εr as a relative permittivity εr of the first dielectric layer to calculate the physical quantity. Instead of directly calculating the relative permittivity εr of the second dielectric layer in reference to the measured capacitance Cs as described above, the value on which the relative permittivity εr is reflected may be obtained so that the command value is calculated in reference to the obtained value.

In the above-described transducer device, it is preferred that the third electrode layer be located on a side of opposite sides of the second dielectric layer in the thickness direction that corresponds to the first electrode layer and separated from the first electrode layer and the fourth electrode layer be located on a side of the opposite sides of the second dielectric layer in the thickness direction that corresponds to the second electrode layer and separated from the second electrode layer.

In the above-described transducer device, it is preferred that the third electrode layer be located on a side of opposite sides of the second dielectric layer in the thickness direction that corresponds to the first electrode layer and provided continuously from the first electrode layer and the fourth electrode layer be located on a side of the opposite sides of the second dielectric layer in the thickness direction that corresponds to the second electrode layer and separated from the second electrode layer.

In the above-described configuration, among the wires that connect the first to fourth electrode layers to the controller, the wire that connects the controller to the third electrode layer and the wire that connects the controller to the first electrode layer are commonized. This reduces the amount of wiring between the controller and the first to fourth electrode layers.

In the above-described transducer device, it is preferred that the third electrode layer be located on a side of opposite sides of the second dielectric layer in the thickness direction that corresponds to the first electrode layer and separated from the first electrode layer and the fourth electrode layer be located on a side of the opposite sides of the second dielectric layer in the thickness direction that corresponds to the second electrode layer and provided continuously from the second electrode layer.

In the above-described configuration, among the wires that connect the first to fourth electrode layers to the controller, the wire that connects the controller to the fourth electrode layer and the wire that connects the controller to the second electrode layer are commonized. This reduces the amount of wiring between the controller and the first to fourth electrode layers.

In the above-described transducer device, it is preferred that the first dielectric layer, the first electrode layer, and the second electrode layer configure a transducer portion, the second dielectric layer, the third electrode layer, and the fourth electrode layer configure a measurement portion, and the transducer portion and the measurement portion be arranged in contact with a common heat transfer plate.

In the above-described configuration, heat is transferred between the first dielectric layer of the transducer portion and the second dielectric layer of the measurement portion through the heat transfer plate. Thus, the temperatures of the first dielectric layer and the second dielectric layer become still closer to each other. Accordingly, when the permittivity εr of the second dielectric layer is used as the permittivity εr of the first dielectric layer, the permittivity εr can be set to a more appropriate value.

### BRIEF DESCRIPTION OF THE DRAWINGS

FIG. 1 is a cross-sectional view schematically showing a transducer device according to a first embodiment that functions as an actuator.

FIG. 2 is a cross-sectional view schematically showing a transducer device according to a second embodiment that functions as a sensor.

FIG. 3 is a perspective view schematically showing the transducer device of FIG. 2 as viewed obliquely from above.

FIG. 4 is a perspective view schematically showing a transducer device according to a third embodiment that functions as a sensor.

FIG. 5 is a plan view showing a state in which the transducer device in FIG. 4 is developed.

FIG. 6 is a cross-sectional view schematically showing another example of a transducer device.

### DETAILED DESCRIPTION OF THE PREFERRED EMBODIMENTS

### First Embodiment

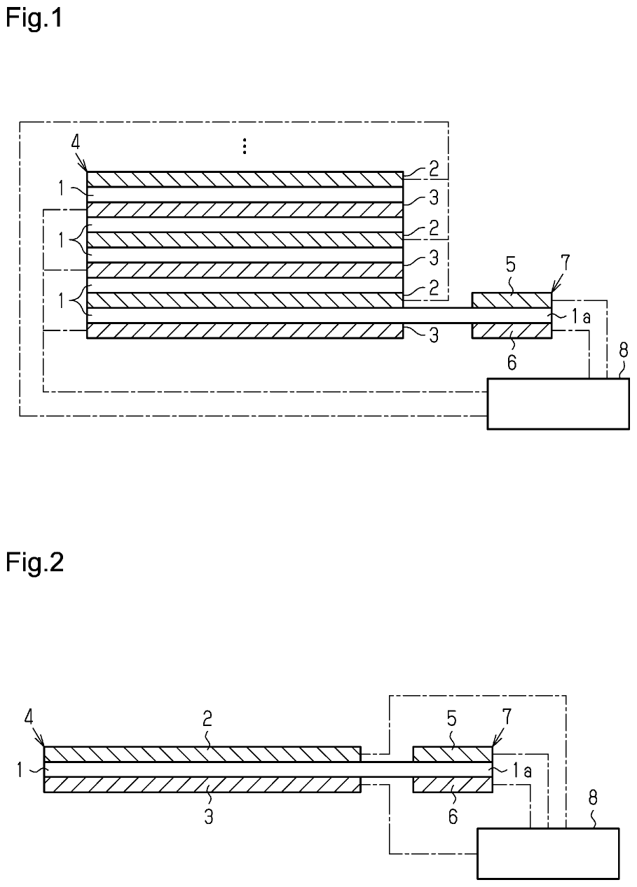

A transducer device according to a first embodiment will now be described with reference to FIG. 1.

As shown in FIG. 1, the transducer device of the first embodiment includes a large number of dielectric elastomer layers 1 with a large number of first conductive rubber layers 2 and second conductive rubber layers 3. The dielectric elastomer layers 1 are made of crosslinked polyrotaxane. Each dielectric elastomer layer 1 is held between the corresponding first conductive rubber layer 2 and second conductive rubber layer 3 in the thickness direction to configure a positive electrode and a negative electrode. The first conductive rubber layer 2 and the second conductive rubber layer 3 are made of conductive silicone elastomer. The dielectric elastomer layer 1, the first conductive rubber layer 2, and the second conductive rubber layer 3 respectively serve as a first dielectric layer, a first electrode layer, and a second electrode layer. In the device, a large number of dielectric elastomer layers 1, first conductive rubber layers 2, and second conductive rubber layers 3 configure a transducer portion 4.

One of the dielectric elastomer layers 1 in the device includes a measurement part 1a, which is provided continuously from the dielectric elastomer layer 1. Thus, in the same manner as the dielectric elastomer layers 1, the measurement part 1a is made of crosslinked polyrotaxane. The measurement part 1a is held by a third conductive rubber layer 5 and a fourth conductive rubber layer 6 from the opposite sides in the thickness direction. In the same manner as the first conductive rubber layers 2 and the second conductive rubber layers 3, the third conductive rubber layer 5 and the fourth conductive rubber layer 6 are made of conductive silicone elastomer.

The third conductive rubber layer 5 is located on a side of the opposite sides of the measurement part 1a in the thickness direction that corresponds to the first conductive rubber layer 2 and separated from the first conductive rubber layer 2. The fourth conductive rubber layer 6 is located on a side of the opposite sides of the measurement part 1a in the thickness direction that corresponds to the second conductive rubber layer 3 and separated from the second conductive rubber layer 3. The measurement part 1a, the third conductive rubber layer 5, and the fourth conductive rubber layer 6 respectively serve as a second dielectric layer, a third electrode layer, and a fourth electrode layer. In the device, the measurement part 1a, the third conductive rubber layer 5, and the fourth conductive rubber layer 6 configure a measurement portion 7.

The device includes a controller 8, which is connected to the first conductive rubber layers 2, the second conductive rubber layers 3, the third conductive rubber layer 5, and the fourth conductive rubber layer 6. The controller 8 calculates a command value Vt of voltage to be applied to the first conductive rubber layers 2 and the second conductive rubber layers 3 and applies a voltage corresponding to the command value Vt to the first conductive rubber layers 2 and the second conductive rubber layers 3 so that each dielectric elastomer layer 1 held by the corresponding first conductive rubber layer 2 and the corresponding second conductive rubber layer 3 is deformed so as to shrink in the thickness direction. When the controller 8 stops applying a voltage to the first conductive rubber layers 2 and the second conductive rubber layers 3, each dielectric elastomer layer 1 restores to the original thickness.

The calculation of the command value Vt executed by the controller 8 will now be described in detail.

The controller 8 measures a capacitance Cs of the measurement part 1a via the third conductive rubber layer 5 and the fourth conductive rubber layer 6 and calculates the command value Vt in reference to the measured capacitance Cs.

In more detail, the controller 8 uses the following equation (1) to calculate a relative permittivity εr of the measurement part 1a in reference to the measured capacitance Cs, an electric constant ε0, the area S of each electrode layer, the thickness t of each dielectric layer, and a stray capacity C0 of each dielectric layer.

$$Cs = ɛ 0 \cdot ɛ r \cdot \frac{s}{t} + C 0 = ɛ 0 \cdot ɛ r \cdot \frac{Vol}{{t}^{2}} + C 0 \qquad ( 1 )$$

Vol: the volume of a dielectric layer between electrode layers (S·t)

When equation (1) is used to calculate the relative permittivity εr of the measurement part 1a, the flat cross sectional area of a portion of the measurement part 1a held by the third conductive rubber layer 5 and the fourth conductive rubber layer 6 is used as the area S, the thickness of the measurement part 1a is used as the thickness t, and the stray capacity (a component of the capacitance that is not intended by a designer) of the measurement part 1a or the controller 8 is used as the stray capacity C0. The electric constant ε0 is a vacuum permittivity. These parameters are fixed values that have been obtained in advance.

The controller 8 calculates the command value Vt using, as the relative permittivity εr of each dielectric elastomer layer 1, the relative permittivity εr of the measurement part 1a obtained as described above. In detail, a necessary value is substituted into each parameter in the following equation (2) to calculate a voltage V, and the calculated voltage V is set as the command value Vt.

$$Δ L = L - t = ɛ 0 \cdot ɛ r \cdot {( \frac{V}{t} )}^{2} \cdot \frac{L}{Y} \qquad ( 2 )$$

When equation (2) is used to calculate the command value Vt, the Young's modulus of the dielectric elastomer layer 1 is used as a Young's modulus Y and the thickness L of the dielectric elastomer layer 1 with no voltage applied is used. The electric constant ε0 is a vacuum permittivity. These parameters are fixed values that have been obtained in advance.

The controller 8 sets, as a deformation amount ΔL, a target value of the deformation amount of the dielectric elastomer layer 1 in the thickness direction. The thickness t of the dielectric elastomer layer 1 with a voltage applied is a variable value and is represented as “L−ΔL.” Further, the relative permittivity εr calculated in equation (1) as described above is set as the relative permittivity εr of the dielectric elastomer layer 1 used for equation (2). Equation (2) is used to calculate the voltage V in reference to the deformation amount ΔL, the relative permittivity εr, the electric constant ε0, the thickness t, the Young's modulus Y, and the thickness L, and the calculated voltage V is set as the command value Vt.

The operation of the transducer device of the first embodiment will now be described.

The command value Vt is calculated using equation (2) in reference to, for example, the relative permittivity εr of the dielectric elastomer layer 1. Further, the relative permittivity εr used in equation (2) is the relative permittivity εr of the measurement part 1a calculated by equation (1). Since the measurement part 1a is provided continuously from the dielectric elastomer layer 1, the measurement part 1a receives the same influence from the surrounding environment (for example, temperature or humidity) as the influence on the dielectric elastomer layer 1 from the surrounding environment. For this reason, the relative permittivity εr of the measurement part 1a is equal to the relative permittivity εr of the dielectric elastomer layer 1.

Accordingly, when the relative permittivity εr of the measurement part 1a calculated as described above is used as the relative permittivity εr of the dielectric elastomer layer 1 to calculate the command value Vt, the calculated command value Vt is a value set taking into account the changes in the relative permittivity εr that correspond to the surrounding environment of the dielectric elastomer layer 1. When the voltage corresponding to the command value Vt is applied to each first conductive rubber layer 2 and each second conductive rubber layer 3, the application of the voltage to the first conductive rubber layer 2 and the second conductive rubber layer 3 is executed by taking into account the surrounding environment of the corresponding dielectric elastomer layer 1. As a result, the deformation amount when the dielectric elastomer layer 1 deforms as a result of the application of the voltage to the first conductive rubber layer 2 and the second conductive rubber layer 3 is prevented from deviating from an intended value due to the surrounding environment of the dielectric elastomer layer 1.

If the prevention of such deviation is hypothetically achieved by correcting the command value Vt, the changes in the deformation characteristics of the dielectric elastomer layer 1 resulting from the changes in the surrounding environment of the dielectric elastomer layer 1 need to be stored as data so that the command value Vt is corrected in reference to the data. This consumes the time and effort to store the data. However, in the transducer device of the first embodiment, preventing the deviation does not consume such time or effort.

The transducer device of the first embodiment described above in detail has the following advantage.

(1) The deformation amount of the dielectric elastomer layer 1 in the thickness direction when the voltage corresponding to the command value Vt is applied to the first conductive rubber layer 2 and the second conductive rubber layer 3 is prevented from deviating from an intended value due to the surrounding environment of the dielectric elastomer layer 1 without consuming time or effort.

### Second Embodiment

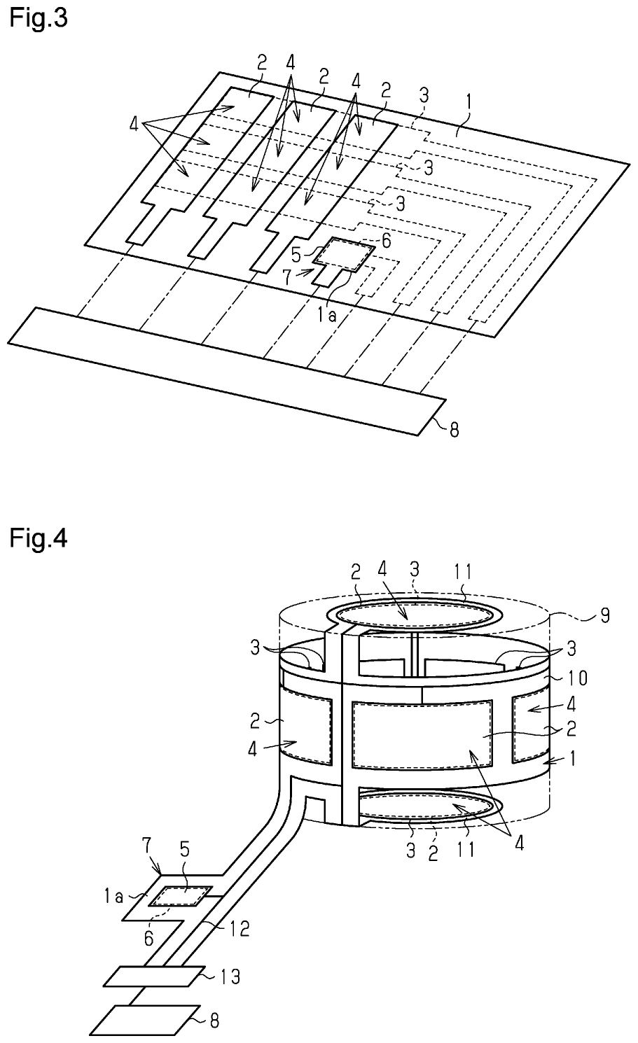

A transducer device according to a second embodiment will now be described with reference to FIGS. 2 and 3. The transducer device of the second embodiment functions as a sensor. In the transducer device of the second embodiment, the same reference numerals are given to the components that are the same as those of the transducer device of the first embodiment. Such components will not be described.

As shown in FIG. 2, the transducer device of the second embodiment includes one dielectric elastomer layer 1 with the first conductive rubber layer 2 and the second conductive rubber layer 3 holding the dielectric elastomer layer 1 in the thickness direction. The dielectric elastomer layer 1 includes the measurement part 1a, which is provided continuously from the dielectric elastomer layer 1. The measurement part 1a is held between the third conductive rubber layer 5 and the fourth conductive rubber layer 6 from the opposite sides in the thickness direction. The third conductive rubber layer 5 is separated from the first conductive rubber layer 2, and the fourth conductive rubber layer 6 is separated from the second conductive rubber layer 3. In the device, the dielectric elastomer layer 1, the first conductive rubber layer 2, and the second conductive rubber layer 3 configure the transducer portion 4, and the measurement part 1a, the third conductive rubber layer 5, and the fourth conductive rubber layer 6 configure the measurement portion 7.

As shown in FIG. 3, multiple first conductive rubber layers 2, second conductive rubber layers 3, and transducer portions 4 are provided. The multiple first conductive rubber layers 2 extend along the dielectric elastomer layer 1, and are spaced apart from each other and arranged parallel to each other. The multiple second conductive rubber layers 3 extend along the dielectric elastomer layer 1, and are spaced apart from each other and arranged parallel to each other. The extending direction of the first conductive rubber layer 2 and the extending direction of the second conductive rubber layer 3 differ from each other by approximately 90°. The multiple first conductive rubber layers 2 are connected to the controller 8, and the multiple second conductive rubber layers 3 are connected to the controller 8.

The third conductive rubber layer 5 and the fourth conductive rubber layer 6 are arranged at a portion of the dielectric elastomer layer 1 that is not held by the first conductive rubber layers 2 or the second conductive rubber layers 3. The third conductive rubber layer 5 and the fourth conductive rubber layer 6 are connected to the controller 8.

The transducer device of the second embodiment functions as a sensor that detects pressure or deformation amount as the physical quantity acting on the dielectric elastomer layer 1. The controller 8 of the device uses the changes in the capacitance of the transducer portion 4 to calculate the physical quantity (pressure or deformation amount) acting on the dielectric elastomer layer 1. The controller 8 detects, according to which transducer portion 4 has changed in capacitance, a position of the dielectric elastomer layer 1 on which the physical quantity acts.

The calculation of the physical quantity acting on the dielectric elastomer layer 1 executed by the controller 8 will now be described in detail.

The controller 8 measures the capacitance Cs of the measurement part 1a, on which no external force acts, via the third conductive rubber layer 5 and the fourth conductive rubber layer 6 and calculates the physical quantity in reference to the measured capacitance Cs.

In more detail, the controller 8 uses the above-described equation (1) to calculate the relative permittivity εr of the measurement part 1a in reference to the measured capacitance Cs, the electric constant ε0, the area S, the thickness t, and the stray capacity C0. Further, the controller 8 calculates the physical quantity using, as the relative permittivity εr of the dielectric elastomer layer 1, the relative permittivity εr of the measurement part 1a obtained in such a manner.

When the deformation amount ΔL (L−t) of the dielectric elastomer layer 1, on which external force acts, in the direction of the thickness t, is calculated as the physical quantity, the relative permittivity εr calculated in the above-described equation (1) is substituted into the relative permittivity εr in the above-described equation (1). In other words, the relative permittivity εr of the measurement part 1a is substituted as the relative permittivity εr of the dielectric elastomer layer 1. Additionally, a necessary value is substituted into each parameter in equation (1) to calculate the deformation amount ΔL. The thickness L is the thickness of the dielectric elastomer layer 1 with no external force acting thereon.

The operation of the transducer device of the second embodiment will now be described.

When the relative permittivity εr of the measurement part 1a calculated as described above is used as the relative permittivity εr of the dielectric elastomer layer 1 to calculate the deformation amount ΔL, the calculated deformation amount ΔL is a value set taking into account the changes in the relative permittivity εr that correspond to the surrounding environment of the dielectric elastomer layer 1. In such a manner, the changes in the relative permittivity εr that correspond to the surrounding environment of the dielectric elastomer layer 1 is taken into account to calculate the deformation amount ΔL. This prevents the physical quantity acting on the dielectric elastomer layer 1 detected by the transducer device from deviating from an appropriate value due to the surrounding environment of the dielectric elastomer layer 1.

When the transducer device of the second embodiment is used to measure the motion of a human body, the relative permittivity εr is affected by salt and lipid contained in, for example, sweat. Even in such a case, the deviation from the appropriate value is prevented.

The transducer device of the second embodiment described above in detail has the following advantage.

(2) The physical quantity detected by the transducer device that functions as a sensor is prevented from deviating from an appropriate value due to the surrounding environment of the dielectric elastomer layer 1 without consuming time or effort.

### Third Embodiment

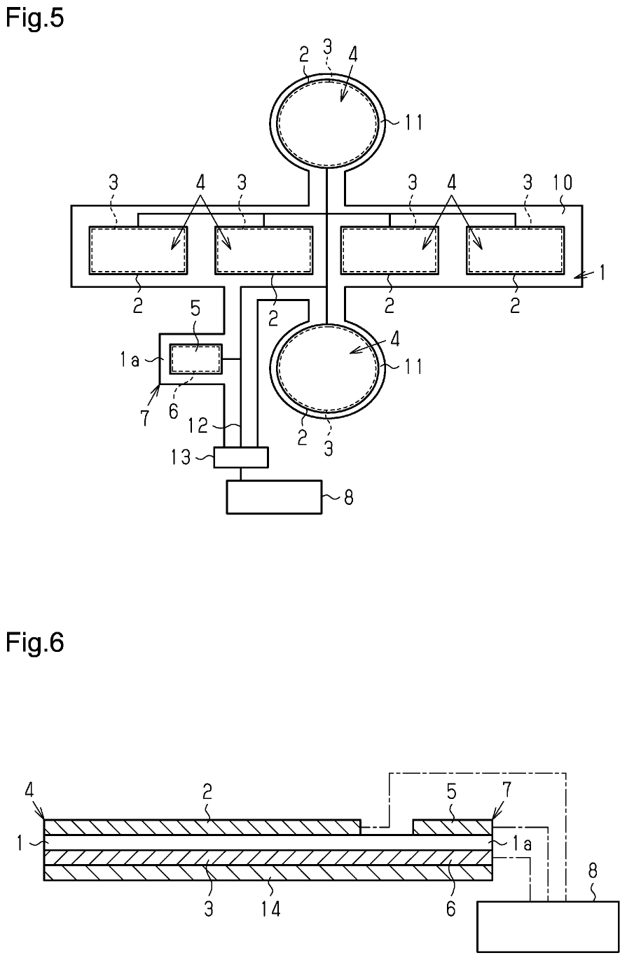

A transducer device according to a third embodiment will now be described with reference to FIGS. 4 and 5. The transducer device of the third embodiment functions as a sensor. In the transducer device of the third embodiment, the same reference numerals are given to the components that are the same as those of the transducer device of the second embodiment. Such components will not be described.

As shown in FIG. 4, the transducer device of the third embodiment is bonded to the side circumferential surface and opposite end surfaces of a cylindrical elastomer 9, which is made of, for example, crosslinked polyrotaxane or silicone. The transducer device of the third embodiment detects the magnitude (deformation amount) and direction of the deformation of the cylindrical elastomer 9. The dielectric elastomer layer 1 in the device is arranged to cover the side circumferential surface and opposite end surfaces of the cylindrical elastomer 9. Further, the first conductive rubber layers 2 and the second conductive rubber layers 3 in the device are arranged to hold the dielectric elastomer layer 1 in the thickness direction.

As shown in FIG. 5, the dielectric elastomer layer 1 includes a belt 10, which covers the side circumferential surface of the cylindrical elastomer 9, and two circular portions 11, which protrude from the belt 10 to cover the opposite end surfaces of the cylindrical elastomer 9. Further, the measurement part 1a of the dielectric elastomer layer 1 extends so as to protrude from the belt 10.

The first conductive rubber layers 2 are arranged in parallel to each other and spaced apart from each other in the belt 10 of the dielectric elastomer layer 1 in the longitudinal direction of the belt 10. The first conductive rubber layers 2 are also arranged on the circular portions 11 of the dielectric elastomer layer 1. In the same manner as the first conductive rubber layers 2, the second conductive rubber layers 3 are arranged in parallel to each other and spaced apart from each other in the belt 10 of the dielectric elastomer layer 1 in the longitudinal direction of the belt 10. The second conductive rubber layers 3 are also arranged on the circular portions 11 of the dielectric elastomer layer 1. The first conductive rubber layers 2 and the second conductive rubber layers 3 in FIG. 5 may each be provided as a single layer or provided as multiple layers arranged in parallel to each other as shown in FIG. 3.

The measurement part 1a of the dielectric elastomer layer 1 is held by the third conductive rubber layer 5 and the fourth conductive rubber layer 6 in the thickness direction of the measurement part 1a (the direction orthogonal to the sheet of FIG. 5). The transducer device includes a wire harness 12, which connects each pair of the first conductive rubber layer 2 and the second conductive rubber layer 3 to the controller 8 and connects the third and fourth conductive rubber layer 5 and 6 to the controller 8. The wire harness 12 includes a connector 13, which is used for the connection to the controller 8.

The wire harness 12 internally includes wires that connect the first conductive rubber layer 2, the second conductive rubber layer 3, the third conductive rubber layer 5, and the fourth conductive rubber layer 6 to the controller 8. These wires may be independent from one another. Alternatively, the wire connected to the second conductive rubber layer 3 and the wire connected to the fourth conductive rubber layer 6 may be coupled to each other.

The transducer device of the third embodiment has the following advantage in addition to advantage (2) of the second embodiment.

(3) When the cylindrical elastomer 9 deforms, each part of the dielectric elastomer layer 1 individually deforms in the thickness direction in accordance with the deformation (for example, deformation amount or deformation direction) of the cylindrical elastomer 9. Such deformation of each part of the dielectric elastomer layer 1 changes the capacitance of the corresponding transducer portion 4. In reference to the changes, the controller 8 calculates the physical quantity acting on the transducer portion 4. In reference to the physical quantity of each part of the dielectric elastomer layer 1 calculated by the controller 8, the transducer device detects the deformation (for example, deformation amount or deformation direction) of the cylindrical elastomer 9.

When the controller 8 calculates the physical quantity acting on each part of the dielectric elastomer layer 1, the relative permittivity εr of the measurement part 1a is used as the relative permittivity εr of the dielectric elastomer layer 1 for the calculation. This prevents the calculated physical quantity from deviating from an appropriate value due to the surrounding environment of the dielectric elastomer layer 1. Accordingly, the deformation amount or deformation direction of the cylindrical elastomer 9 detected by the transducer device is set to be appropriate and unaffected by the surrounding environment of the dielectric elastomer layer 1.

Modifications

For example, each of the above-described embodiments may be modified as follows.

In the third embodiment, the wire harness 12 does not necessarily have to be employed as each of the wires that connect the first conductive rubber layer 2, the second conductive rubber layer 3, the third conductive rubber layer 5, and the fourth conductive rubber layer 6 to the controller 8. That is, each wire may be arranged individually instead of being used as a wire harness. In this case, the wires may be made of the same material as the conductive rubber layers 2, 3, 5, and 6 or may be made of different materials.

In the first and second embodiments, as shown in FIG. 6, the fourth conductive rubber layer 6 may be provided continuously from the second conductive rubber layer 3. In this structure, among the wires that connect the first conductive rubber layer 2, the second conductive rubber layer 3, the third conductive rubber layer 5, and the fourth conductive rubber layer 6 to the controller 8, the wire that connects the fourth conductive rubber layer 6 to the controller 8 and the wire that connects the second conductive rubber layer 3 to the controller 8 may be commonized. This reduces the amount of wiring between the controller 8 and the first, second, third, and fourth conductive rubber layers 2, 3, 5, and 6.

In a case where the fourth conductive rubber layer 6 is separated from the second conductive rubber layer 3 like in the first and second embodiments, the third conductive rubber layer 5 may be provided continuously from the first conductive rubber layer 2. In this structure, among the wires that connect the first conductive rubber layer 2, the second conductive rubber layer 3, the third conductive rubber layer 5, and the fourth conductive rubber layer 6 to the controller 8, the wire that connects the third conductive rubber layer 5 to the controller 8 and the wire that connects the first conductive rubber layer 2 to the controller 8 may be commonized. This reduces the amount of wiring between the controller 8 and the first, second, third, and fourth conductive rubber layers 2, 3, 5, and 6.

In the first and second embodiments, as shown in FIG. 6, the transducer portion 4 and the measurement portion 7 may be arranged in contact with a common heat transfer plate 14. In this structure, heat is transferred between the dielectric elastomer layer 1 of the transducer portion 4 and the measurement part 1a of the measurement portion 7 through the heat transfer plate 14. Thus, the temperatures of the dielectric elastomer layer 1 and the measurement part 1a become still closer to each other. Accordingly, when the relative permittivity εr of the measurement part 1a is used as the relative permittivity εr of the dielectric elastomer layer 1, the relative permittivity εr can be set to a more appropriate value.

In the first and second embodiments, the dielectric elastomer layer 1 and the measurement part 1a are manufactured to have the same thickness. Instead, the dielectric elastomer layer 1 and the measurement part 1a may be manufactured to have different thicknesses.

In the first to third embodiments, the first conductive rubber layer 2 and the second conductive rubber layer 3 are arranged proximate to the outermost part of the transducer device. Instead, the entire device may be covered by an insulative elastomer made of, for example, silicone or crosslinked polyrotaxane.

1. A transducer device comprising:
a first dielectric layer;
a first electrode layer and a second electrode layer that hold the first dielectric layer in a thickness direction;
a second dielectric layer on which no external force acts, the second dielectric layer being provided continuously from the first dielectric layer;
a third electrode layer and a fourth electrode layer that hold the second dielectric layer in the thickness direction; and
a controller that calculates a command value of voltage to be applied to the first electrode layer and the second electrode layer and applies a voltage corresponding to the command value to the first electrode layer and the second electrode layer so that the first dielectric layer is deformed in the thickness direction,
wherein the controller measures a capacitance Cs of the second dielectric layer via the third electrode layer and the fourth electrode layer and calculates the command value in reference to the measured capacitance Cs.

2. The transducer device according to claim 1, wherein the controller obtains a relative permittivity εr of the second dielectric layer in reference to the measured capacitance Cs and uses the relative permittivity εr as a relative permittivity εr of the first dielectric layer to calculate the command value.

3. A transducer device, comprising:
a first dielectric layer;
a first electrode layer and a second electrode layer that hold the first dielectric layer in a thickness direction;
a second dielectric layer on which no external force acts, the second dielectric layer being provided continuously from the first dielectric layer;
a third electrode layer and a fourth electrode layer that hold the second dielectric layer in the thickness direction; and
a controller that calculates a physical quantity acting on the first dielectric layer in reference to an electrical signal from the first electrode layer and the second electrode layer,
wherein the controller measures a capacitance Cs of the second dielectric layer via the third electrode layer and the fourth electrode layer and calculates the physical quantity in reference to the measured capacitance Cs.

4. The transducer device according to claim 3, wherein the controller obtains a relative permittivity εr of the second dielectric layer in reference to the measured capacitance Cs and uses the relative permittivity εr as a relative permittivity εr of the first dielectric layer to calculate the physical quantity.

5. The transducer device according to claim 1, wherein
the third electrode layer is located on a side of opposite sides of the second dielectric layer in the thickness direction that corresponds to the first electrode layer and separated from the first electrode layer, and
the fourth electrode layer is located on a side of the opposite sides of the second dielectric layer in the thickness direction that corresponds to the second electrode layer and separated from the second electrode layer.

6. The transducer device according to claim 1, wherein
the third electrode layer is located on a side of opposite sides of the second dielectric layer in the thickness direction that corresponds to the first electrode layer and provided continuously from the first electrode layer, and
the fourth electrode layer is located on a side of the opposite sides of the second dielectric layer in the thickness direction that corresponds to the second electrode layer and separated from the second electrode layer.

7. The transducer device according to claim 1, wherein
the third electrode layer is located on a side of opposite sides of the second dielectric layer in the thickness direction that corresponds to the first electrode layer and separated from the first electrode layer, and
the fourth electrode layer is located on a side of the opposite sides of the second dielectric layer in the thickness direction that corresponds to the second electrode layer and provided continuously from the second electrode layer.

8. The transducer device according to claim 1, wherein
the first dielectric layer, the first electrode layer, and the second electrode layer configure a transducer portion,
the second dielectric layer, the third electrode layer, and the fourth electrode layer configure a measurement portion, and
the transducer portion and the measurement portion are arranged in contact with a common heat transfer plate.

9. The transducer device according to claim 3, wherein
the third electrode layer is located on a side of opposite sides of the second dielectric layer in the thickness direction that corresponds to the first electrode layer and separated from the first electrode layer, and
the fourth electrode layer is located on a side of the opposite sides of the second dielectric layer in the thickness direction that corresponds to the second electrode layer and separated from the second electrode layer.

10. The transducer device according to claim 3, wherein
the third electrode layer is located on a side of opposite sides of the second dielectric layer in the thickness direction that corresponds to the first electrode layer and provided continuously from the first electrode layer, and
the fourth electrode layer is located on a side of the opposite sides of the second dielectric layer in the thickness direction that corresponds to the second electrode layer and separated from the second electrode layer.

11. The transducer device according to claim 3, wherein
the third electrode layer is located on a side of opposite sides of the second dielectric layer in the thickness direction that corresponds to the first electrode layer and separated from the first electrode layer, and
the fourth electrode layer is located on a side of the opposite sides of the second dielectric layer in the thickness direction that corresponds to the second electrode layer and provided continuously from the second electrode layer.

12. The transducer device according to claim 3, wherein
the first dielectric layer, the first electrode layer, and the second electrode layer configure a transducer portion,
the second dielectric layer, the third electrode layer, and the fourth electrode layer configure a measurement portion, and
the transducer portion and the measurement portion are arranged in contact with a common heat transfer plate.
